(19) United States
(12) Patent Application Publication
(10) Pub. No.: US 2008/0292523 A1
(43) Pub. Date: Nov. 27, 2008

(54) SILICON SINGLE CRYSTAL WAFER AND THE PRODUCTION METHOD

(75) Inventors: Toshiaki ONO, Tokyo (JP); Takayuki KIHARA, Tokyo (JP)

Correspondence Address: GREENBLUM & BERNSTEIN, P.L.C., 1950 ROLAND CLARKE PLACE, RESTON, VA, 20191, US

(73) Assignee: SUMCO Corporation, Tokyo (JP)

(21) Appl. No.: 12/113,576

(22) Filed: May 1, 2008

(30) Foreign Application Priority Data
May 23, 2007 (JP) 2007-136287
Aug. 22, 2007 (JP) 2007-215518

(51) Int. Cl. C01B 33/02; C30B 15/00

(52) U.S. Cl. 423/348; 117/20

(57) ABSTRACT

A production method of a silicon single crystal wafer capable of effectively bringing out a gettering effect also in a thin film device is provided: wherein a thermal treatment with rapid heating up and down is performed for 10 seconds or shorter on a silicon single crystal wafer obtained by processing a single crystal grown by the Czochralski method and having an initial interstitial oxygen density is 1.4×10¹⁸ atoms/cc (ASTM F-121, 1979).

### BACKGROUND OF THE INVENTION

1. Field of the Invention

The present invention relates to a silicon single crystal wafer and the production method, and particularly relates to a silicon single crystal wafer which is also suitable to a thin film device and the production method.

2. Description of the Related Art

In methods of producing a silicon single crystal wafer having an excellent gettering capability, there has been a proposal for eliminating COP (Crystal Originated Particles) near a surface layer of an annealed wafer by performing a thermal treatment at a temperature of 1100° C. or higher in a nonoxidizing atmosphere (refer to the Patent Article 1).

However, in this method, outward diffusion of oxygen is caused at the same time. Therefore, in a wafer obtained by this method, an area with no oxygen precipitate (BMD: Bulk Micro Defect) existing therein is formed to be in a depth of 10 μm or deeper from the wafer surface.

In recent years, semiconductor devices have become furthermore thinner and, along with that, there has been a demand for wafers having their gettering layers explained above closer to the device active layers.

However, in the production method of the related art explained above, as a result of the thermal treatment for improving the gettering capability, an area with no oxygen precipitate existing therein is formed to be as deep as 10 μm or deeper from the wafer surface; therefore, there has been a demand for developing a method for producing a wafer which can bring out the full efficiency of the gettering effect even in a thin film device.

On the other hand, a semiconductor integrated circuit (device) uses as its substrate a wafer cut out from an ingot-formed single crystal made, for example, by silicone and undergoes a number of processes of forming a circuit thereon so as to be a product. The processes include various physical treatments, chemical treatments and, furthermore, thermal treatments; and also include treatments under a severe condition of exceeding 1000° C. Therefore, a minute defect called “Grown-in defect” arises: a cause thereof is formed when growing the single crystal, becomes apparent during the production process of the device and largely affects the quality. Note that the “Grown-in defect” here indicates, by taking an example of a silicon single crystal formed by the Czochralski method (CZ method), a hole defect having a size of about 0.1 to 0.2 μm called an infrared scattering defect or a COP (Crystal Originated Particle), etc., or a defect due to minute dislocation having a size of about 10 μm called dislocation cluster.

In recent years, technologies for solving disadvantages of the Grown-in defects as explained above have been proposed. For example, the Patent Article 2 discloses a method of growing a single crystal by pulling up a seed crystal by using a single crystal pulling apparatus (growing apparatus) using the CZ method with an improved hot zone structure as a cooling portion immediately after solidification in pulling up a single crystal as a material, setting an atmosphere in the apparatus to an inert gas atmosphere including hydrogen and, furthermore, keeping a hydrogen partial pressure in the atmosphere to be within a predetermined range (40 to 400 Pa). By using this method, a constant diameter part of the single crystal to be obtained can be grown to be a defect-free are with no Grown-in defect exists therein. When cutting out from a thus grown silicon ingot, a silicon wafer with no Grown-in defect can be obtained.

In recent years, technologies for manufacturing a silicon wafer having an excellent gettering capability have been proposed. For example, the Patent Article 2 discloses a technology of eliminating COP near an annealed wafer surface layer by performing a thermal treatment at 1100° C. or higher in a nonoxidizing atmosphere on a wafer cut out from a silicon ingot.

In this method, however, outward diffusion of oxygen is caused at the same time. Therefore, in a wafer obtained by this method, an area without any defects called oxygen precipitate (BMD: Bulk Micro Defect) having a gettering action existing therein is formed to be as much as 10 μm or deeper from the wafer surface, and it cannot be said that a sufficient gettering capability is obtained.

In recent years, semiconductor devices themselves have become thinner and, along with that, there have been demands for a wafer wherein BMD having a gettering action exists closer to the device active layer.

In a silicon wafer with no Grown-in defect, it is known that an oxygen precipitation behavior is largely different in the density from that in a dominant point defects type. A defect-free area is formed by areas where vacancies are enriched and areas where interstitial silicon atoms are enriched. The BMD having a gettering action is formed in the areas where vacancies are enriched, however, when performing a thermal treatment at 800° C. for four hours and 1000° C. for 16 hours, the BMD is formed in a deeper area than 10 μm from the wafer surface layer and formation thereof in the wafer surface layer cannot be expected. Furthermore, in the areas where interstitial silicon atoms are enriched, formation of BMD is suppressed from the beginning.
[Patent Article 1] The Japanese Unexamined Patent Publication No. H10-144698
[Patent Article 2] The Japanese Unexamined Patent Publication No. 2006-312575

### SUMMARY OF THE INVENTION

An object of the present invention is to provide a silicon single crystal wafer capable of bringing out a gettering effect efficiently also in a thin film device and the production method.

Another object of the present invention is to provide a silicon single crystal wafer capable of bringing out a gettering effect efficiently even in a thin film device: wherein BMD exists at a high density in a shallow area of, for example, up to 10 μm from the surface layer but no defect exists in its extreme surface layer acting as a device active layer even if it is cut out from a crystal which is grown under a no defect condition that no Grown-in defect exists when growing the crystal; and the production method.

The present invention provides a silicon wafer obtained by processing a single crystal grown by the Czochralski method and performing a thermal treatment with rapid heating up and down for 10 seconds or shorter on a wafer having an initial interstitial oxygen density of 1.4×10¹⁸ atoms/cc (ASTM F-121,1979) or higher.

According to the present invention, by performing a thermal treatment with rapid heating up and down for 10 seconds or shorter, COP and oxygen precipitation nuclei are eliminated though only in the surface layer area and a high oxide film breakdown voltage is exhibited in this area. Also, since high oxygen density wafer having an initial interstitial oxygen density of 1.4×10¹⁸ atoms/cc or higher is used, oxygen stable precipitation nuclei exist in an area of 10 μm or so from the surface in the wafer. Accordingly, it is possible to obtain a silicon single crystal wafer wherein crystal defects are eliminated in the wafer surface layer and stable oxygen precipitation nuclei to be gettering sources exist immediately beneath the device active region.

Also, in the present invention, a thermal treatment with rapid heating up and down is performed at 1000° C. or higher for 10 seconds or shorter on a wafer cut out from a silicon ingot having a constant diameter part with no Grown-in defect and having interstitial oxygen density [Oi] of 1.4×10¹⁸ atoms/cm³.

According to the present invention, even a wafer cut out from a crystal grown under a defect-free condition that no Grown-in defect exists when growing the crystal, since a thermal treatment with rapid heating up and down at 1000° C. or higher for 10 seconds or shorter is performed on the wafer, COP and oxygen precipitation nuclei are eliminated though only in the surface layer area and a high oxide film breakdown voltage is exhibited on this area. Also, since a wafer having a high interstitial oxygen density is used, oxygen stable precipitation nuclei exist in an area of 10 μm or so from the surface in the wafer. Accordingly, it is possible to obtain a silicon wafer wherein crystal defects are eliminated in the wafer surface layer and stable oxygen precipitation nuclei to be gettering sources exist immediately beneath the device active region.

### BRIEF DESCRIPTION OF DRAWINGS

These and other objects and features of the present invention will become clearer from the following description of the preferred embodiments given with reference to the attached drawings, in which:

FIG. 1 is a view showing a procedure of a production method of a silicon single crystal wafer according to a first embodiment of the present invention;

FIG. 2 is a schematic sectional view showing an example of a single crystal pulling apparatus used for realizing a production method of a silicon single crystal wafer according to a second embodiment of the present invention; and

FIG. 3 is a view showing a procedure of a production method of a silicon wafer according to the second embodiment of the present invention.

### DESCRIPTION OF THE PREFERRED EMBODIMENT

### First Embodiment

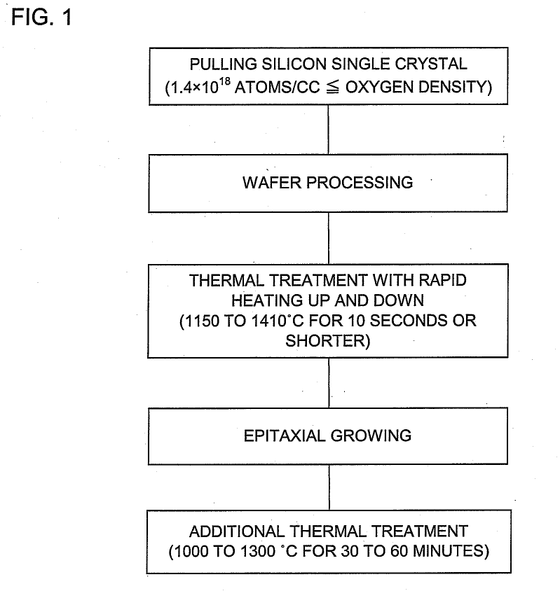

FIG. 1 is a view of a procedure of a production method of a silicon single crystal wafer according to an embodiment of the present invention. In the production method of a silicon single crystal wafer according to the present embodiment, a silicon ingot is grown by the CZ method under a condition that initial interstitial oxygen density is high as 1.4×10¹⁸ atoms/cc (ASTM F-121,1979) or higher. It is because stable oxygen precipitate to become a gettering source does not present by an effective number immediately beneath the thin film device active layer when the oxygen density at growing the silicon is lower than 1.4×10¹⁸ atoms/cc.

During the silicon growing, it is preferable to dope nitrogen in the silicon single crystal by 1×10¹³ to 1×10¹⁵ atoms/cc because the defect-free area becomes larger thereby.

Next, the silicon ingot is processed to be wafers. The wafer processing is not particularly limited and general processing methods may be used.

After the wafer processing, a thermal treatment of rapidly heating up and down at a temperature of 1150° C. or higher but not higher than a melting point of silicon (1410° C.) is performed for 10 seconds or shorter. The thermal treatment of rapidly heating up and down is performed in a nonoxidizing atmosphere, for example, in an atmosphere of an argon gas, nitrogen gas, hydrogen gas or a mixed gas of these.

In the thermal treatment of rapidly heating up and down of the present embodiment, a halogen lamp thermal treatment furnace using a halogen lamp as a heat source, a flush lamp thermal treatment furnace using a xenon lamp as a heat source or a laser thermal treatment furnace using a laser as a heat source may be used. It is preferable to perform the thermal treatment for 0.1 to 10 seconds when using a halogen lamp thermal treatment furnace, 0.1 second or shorter when using a flush lamp thermal treatment furnace, and 0.1 second or shorter when using a laser thermal treatment furnace.

By performing a thermal treatment of rapidly heating up and down as explained above, it is possible to obtain a wafer wherein a defect-free layer is formed on the wafer surface and an oxygen precipitate to be a gettering source exists immediately beneath the device active layer (10 to 20 μm from the wafer surface).

In addition to that, it is possible to grow a silicon epitaxial layer on the wafer surface subjected to the thermal treatment of rapidly heating up and down. Because a defect-free layer is formed on the wafer surface subjected to the thermal treatment of rapidly heating up and down, by forming an epitaxial layer thereon, the defect-free layer can be furthermore increased or a thickness of the defect-free layer becomes adjustable.

Alternately, after performing the thermal treatment of rapidly heating up and down, an additional thermal treatment at 1000° C. to 1300° C. for about 30 to 60 minutes in a nonoxidizing atmosphere may be furthermore performed. By performing the additional thermal treatment, a size of oxygen precipitate existing immediately beneath the device active layer can become larger and a thickness of the defect-free layer becomes adjustable.

In the following examples and comparative examples, it was confirmed that, when a thermal treatment of rapidly heating up and down for 10 seconds or shorter is performed on a wafer grown under a condition of initial interstitial oxygen density of 1.4×10¹⁸ atoms/cc (ASTM F-121,1979) or higher, a surface layer as a device active region exhibits a high oxide film breakdown voltage and oxygen precipitation nuclei to be gettering sources present immediately beneath the device active region.

### EXAMPLE 1

A plurality of silicon wafers obtained by slicing a silicon single crystal ingot (having an initial interstitial oxygen density of 14.5×10¹⁷ atoms/cc (ASTM F-121, 1979) and specific resistance of 10 to 20 Ωcm, no nitrogen dope) having a diameter of 200 nm and performing mirror finish processing thereon were subjected to a thermal treatment at 1150° C. for 3 seconds by using a thermal treatment furnace having a halogen lamp as its heat source.

Each of the silicon wafers subjected to the thermal treatment was polished again by about 0.2 μm to prepare wafers each having a different re-polished amount from its surface. On the wafers each having a different re-polished amount from its surface, an oxide film having a thickness of 25 nm and a MOS capacitor having a measurement electrode (phosphorus-doped polysilicon electrode) having an area of 8 mm² were formed. Then, oxide film breakdown voltage characteristics TZDB were measured under a condition that an electric field for judging was 11 Mv/cm (it was considered breakdown when a current value exceeds 10⁻³ A), and MOS capacitors which cleared the judging electric field were considered to be good. A maximum re-polished amount (hereinafter, also referred to as a defect-free depth) was 1.7 μm in those exhibited good rate of 90%.

On the other hand, on the silicon wafers subjected to the thermal treatment with rapid heating up and down as explained above, a further thermal treatment at 1000° C. for 16 hours was performed, then, the wafers were cleaved and subjected to wright etching of 2 μm. When respectively measuring etching pits existing at 10 to 20 μm from the wafer surfaces and calculating BMD density, it was 2.1×10⁵ pieces/cm².

Results of the defect-free depth and the BMD density are shown in Table 1 with oxygen density, nitrogen density and a condition of the thermal treatment with rapid heating up and down.

### EXAMPLE 2

Comparing with the example 1, other than changing the initial interstitial oxygen density of the silicon single crystal ingot to 22.1×10¹⁷ atoms/cc (ASTM F-121, 1979) and a condition of the thermal treatment with rapid heating up and down using a halogen lamp to 1200° C. for 3 seconds; a wafer was produced under the same condition as that in the example 1 and a defect-free depth and BMD density were measured. The results were 1.8 μm in the defect-free depth and 4.9×10⁵ pieces/cm² in the BMD density.

### EXAMPLE 3

Comparing with the example 1, other than changing the initial interstitial oxygen density of the silicon single crystal ingot to 14.6×10¹⁷ atoms/cc (ASTM F-121, 1979), using a flash lamp thermal treatment furnace using a xenon lamp instead of a halogen lamp and changing a condition of the thermal treatment with rapid heating up and down to 1250° C. for 0.001 second; a wafer was produced under the same condition as that in the example 1 and a defect-free depths and BMD density were measured. The results were 0.6 μm in the defect-free depth and 38.0×10⁵ pieces/cm² in the BMD density.

### EXAMPLE 4

Comparing with the example 1, other than changing the initial interstitial oxygen density of the silicon single crystal ingot to 21.8×10¹⁷ atoms/cc (ASTM F-121, 1979), using a flash lamp thermal treatment furnace using a xenon lamp instead of a halogen lamp and changing a condition of the thermal treatment with rapid heating up and down to 1300° C. for 0.001 second; a wafer was produced under the same condition as that in the example 1 and a defect-free depth and BMD density were measured. The results were 0.8 μm in the defect-free depth and 52.0×10⁵ pieces/cm² in the BMD density.

### EXAMPLE 5

Comparing with the example 1, other than changing the initial interstitial oxygen density of the silicon single crystal ingot to 14.4×10¹⁷ atoms/cc (ASTM F-121, 1979), using a laser thermal treatment furnace using a laser instead of a halogen lamp and changing a condition of the thermal treatment with rapid heating up and down to 1300° C. for 0.001 second; a wafer was produced under the same condition as that in the example 1 and a defect-free depth and BMD density were measured. The results were 0.8 μm in the defect-free depth and 29.0×10⁵ pieces/cm² in the BMD density.

### EXAMPLE 6

Comparing with the example 1, other than changing the initial interstitial oxygen density of the silicon single crystal ingot to 22.3×10¹⁷ atoms/cc (ASTM F-121, 1979), using a laser thermal treatment furnace using a laser instead of a halogen lamp and changing a condition of the thermal treatment with rapid heating up and down to 1350° C. for 0.001 second; a wafer was produced under the same condition as that in the example 1 and a defect-free depth and BMD density were measured. The results were 1.Otm in the defect-free depth and 62.0×10⁵ pieces/cm² in the BMD density.

### EXAMPLE 7

Comparing with the example 1, other than changing the initial interstitial oxygen density of the silicon single crystal ingot to 14.3×10¹⁷ atoms/cc (ASTM F-121, 1979), changing nitrogen density to 1.5×10¹³ atoms/cc, and changing a condition of the thermal treatment with rapid heating up and down using a halogen lamp to 1200° C. for 5 seconds; a wafer was produced under the same condition as that in the example 1 and a defect-free depth and BMD density were measured. The results were 2.6 μm in the defect-free depth and 58.0×10⁵ pieces/cm² in the BMD density.

### EXAMPLE 8

Comparing with the example 1, other than changing the initial interstitial oxygen density of the silicon single crystal ingot to 14.7×10¹⁷ atoms/cc (ASTM F-121, 1979), changing nitrogen density to 85.8×10¹³ atoms/cc, and changing a condition of the thermal treatment with rapid heating up and down using a halogen lamp to 1200° C. for 5 seconds; a wafer was produced under the same condition as that in the example 1 and a defect-free depth and BMD density were measured. The results were 2.3 μm in the defect-free depth and 51.0×10⁵/cm² in the BMD density.

### EXAMPLE 9

Comparing with the example 1, other than changing the initial interstitial oxygen density of the silicon single crystal ingot to 21.1×10¹⁷ atoms/cc (ASTM F-121, 1979), changing nitrogen density to 2.5×10¹³ atoms/cc, and changing a condition of the thermal treatment with rapid heating up and down using a halogen lamp to 1200° C. for 3 seconds; a wafer was produced under the same condition as that in the Example 1 and a defect-free depth and BMD density were measured. The results were 2.1 μm in the defect-free depth and 67.0×10⁵ pieces/cm² in the BMD density.

### EXAMPLE 10

Comparing with the example 1, other than changing the initial interstitial oxygen density of the silicon single crystal ingot to 21.9×10¹⁷ atoms/cc (ASTM F-121, 1979), changing nitrogen density to 75.8×10¹³ atoms/cc, and changing a condition of the thermal treatment with rapid heating up and down using a halogen lamp to 1200° C. for 3 seconds; a wafer was produced under the same condition as that in the example 1 and a defect-free depth and BMD density were measured. The results were 1.7 μm in the defect-free depth and 61.0×10⁵ pieces/cm² in the BMD density.

### EXAMPLE 11

Comparing with the example 1, other than changing the initial interstitial oxygen density of the silicon single crystal ingot to 20.4×10¹⁷ atoms/cc (ASTM F-121, 1979), changing nitrogen density to 34.6×10¹³ atoms/cc, using a flash lamp thermal treatment furnace using a xenon lamp instead of a halogen lamp, and changing a condition of the thermal treatment with rapid heating up and down using a halogen lamp to 1300° C. for 0.001 second; a wafer was produced under the same condition as that in the example 1 and a defect-free depth and BMD density were measured. The results were 0.8 μm in the defect-free depth and 49.0×10⁵ pieces/cm² in the BMD density.

### EXAMPLE 12

Comparing with the example 1, other than changing the initial interstitial oxygen density of the silicon single crystal ingot to 21.0×10¹⁷ atoms/cc (ASTM F-121, 1979), changing nitrogen density to 81.5×10¹³ atoms/cc, using a laser thermal treatment furnace using a laser instead of a halogen lamp, and changing a condition of the thermal treatment with rapid heating up and down using a halogen lamp to 1300° C. for 0.001 second; a wafer was produced under the same condition as that in the example 1 and a defect-free depth and BMD density were measured. The results were 0.8 μm in the defect-free depth and 52.0×10⁵ pieces/cm² in the BMD density.

### COMPARATIVE EXAMPLE 1

Comparing with the example 1, other than changing the initial interstitial oxygen density of the silicon single crystal ingot to 13.1×10¹⁷ atoms/cc (ASTM F-121, 1979) and changing a condition of the thermal treatment with rapid heating up and down using a halogen lamp to 1200° C. for 3 seconds; a wafer was produced under the same condition as that in the example 1 and a defect-free depth and BMD density were measured. The results were 2.1 μm in the defect-free depth but the BMD density was lower than 1.0×10⁴ pieces/cm².

### COMPARATIVE EXAMPLE 2

Comparing with the example 1, other than changing the initial interstitial oxygen density of the silicon single crystal ingot to 13.2×10¹⁷ atoms/cc (ASTM F-121, 1979), changing nitrogen density to 35.0×10¹³ atoms/cc and changing a condition of the thermal treatment with rapid heating up and down using a halogen lamp to 1200° C. for 5 seconds; a wafer was produced under the same condition as that in the example 1 and a defect-free depth and BMD density were measured. The results were 2.6 μm in the defect-free depth but the BMD density was lower than 1.0×10⁴ pieces/cm².

### COMPARATIVE EXAMPLE 3

Comparing with the example 1, other than changing the initial interstitial oxygen density of the silicon single crystal ingot to 14.8×10¹⁷ atoms/cc (ASTM F-121, 1979) and changing a condition of the thermal treatment with rapid heating up and down using a halogen lamp to 1100° C. for 3 seconds; a wafer was produced under the same condition as that in the example 1 and a defect-free depth and BMD density were measured. The results were 6.4×10⁵ pieces/cm² in the BMD density but 0 μm in the defect-free depth.

### COMPARATIVE EXAMPLE 4

Comparing with the example 1, other than changing the initial interstitial oxygen density of the silicon single crystal ingot to 15.2×10¹⁷ atoms/cc (ASTM F-121, 1979) and changing a condition of the thermal treatment with rapid heating up and down using a halogen lamp to 1125° C. for 3 seconds; a wafer was produced under the same condition as that in the example 1 and a defect-free depth and BMD density were measured. The results were 5.3×10⁵ pieces/cm² in the BMD density but 0 μm in the defect-free depth.

TABLE 1

| | | | Thermal Treatment with Rapid Heating | | | | |
|---|---|---|---|---|---|---|---|
| | Silicon Ingot | | Up and Down | | | | |
| | Oxygen | | Thermal | | | Defect-Free | |
| | Density | Nitrogen Density | Treatment | Temperature | Duration | Depth | BMD Density |
| | (×10¹⁷ atoms/cc) | (×10¹³ atoms/cc) | Furnace | (° C.) | (second) | (μm) | (×10⁵ pieces/cm²) |
| Example 1 | 14.5 | no dope | halogen lamp | 1150 | 3 | 1.7 | 2.1 |
| Example 2 | 22.1 | no dope | halogen lamp | 1200 | 3 | 1.8 | 4.9 |
| Example 3 | 14.6 | no dope | flash lamp | 1250 | 0.001 | 0.6 | 38.0 |
| Example 4 | 21.8 | no dope | flash lamp | 1300 | 0.001 | 0.8 | 52.0 |
| Example 5 | 14.4 | no dope | laser | 1300 | 0.001 | 0.8 | 29.0 |
| Example 6 | 22.3 | no dope | laser | 1350 | 0.001 | 1.0 | 62.0 |
| Example 7 | 14.3 | 1.5 | halogen lamp | 1200 | 5 | 2.6 | 58.0 |
| Example 8 | 14.7 | 85.8 | halogen lamp | 1200 | 5 | 2.3 | 51.0 |
| Example 9 | 21.1 | 2.5 | halogen lamp | 1200 | 3 | 2.1 | 67.0 |
| Example 10 | 21.9 | 75.8 | halogen lamp | 1200 | 3 | 1.7 | 61.0 |
| Example 11 | 20.4 | 34.6 | flash lamp | 1300 | 0.001 | 0.8 | 49.0 |
| Example 12 | 21.0 | 81.5 | laser | 1300 | 0.001 | 0.8 | 52.0 |
| Comparative | 13.1 | no dope | halogen lamp | 1200 | 3 | 2.1 | (<1 × 104) |
| Example 1 | | | | | | | |
| Comparative | 13.2 | 35.0 | halogen lamp | 1200 | 5 | 2.6 | (<1 × 104) |
| Example 2 | | | | | | | |
| Comparative | 14.8 | no dope | halogen lamp | 1100 | 3 | 0.0 | 6.4 |
| Example 3 | | | | | | | |
| Comparative | 15.2 | no dope | halogen lamp | 1125 | 3 | 0.0 | 5.3 |
| Example 4 | | | | | | | |

### [Considerations]

It was confirmed from the results of the examples 1 to 12 that, when a wafer having initial interstitial oxygen density of 1.4×10¹⁷ atoms/cc (ASTM F-121, 1979) or higher was subjected to a thermal treatment at 1150° C. or higher and 1350° C. or lower for not longer than 3 seconds, a defect-free layer of about 3 μm or shallower was formed in the obtained wafer.

Namely, it was confirmed that Grown-in (Void) defects COP and oxygen precipitation nuclei which were formed when pulling up by the CZ method were eliminated by the thermal treatment with rapid heating up and down and that the area exhibits a high oxide film breakdown voltage.

On the other hand, it was confirmed that, since the area being 10 to 20 μm from the wafer surface was hyperoxic when growing the crystal, there were grown and stable oxygen precipitation nuclei and they became apparent due to a thermal treatment at 1000° C. for 16 hours.

As explained above, in the examples 1 to 12, it was confirmed that an extremely preferable wafer was obtained, wherein defects were eliminated on the wafer outermost layer and stable oxygen precipitation nuclei (gettering sources) existed immediately beneath the device active region. It was also confirmed that further shallower defect-free layer can be obtained when using a flash lamp thermal treatment furnace and a laser thermal treatment furnace.

On the other hand, in the comparative examples 1 and 2, it was confirmed that stable oxygen precipitation nuclei do not exist even though a thermal treatment with rapid heating up and down or a thermal treatment at 1000° C. was performed for 16 hours, because initial oxygen density existing in the crystal was low so that a sufficiently and stable precipitation nucleus size was not obtained when growing the crystal.

Furthermore, in the comparative examples 3 and 4, it was confirmed that, since a temperature of the thermal treatment with rapid heating up and down was low, defects were not eliminated sufficiently in the thermal treatment with rapid heating up and down and the yield of the oxide film breakdown voltage was deteriorated from the wafer outermost surface.

### EXAMPLE 13

On a plurality of silicon wafers obtained by slicing a silicon single crystal ingot (having an initial interstitial oxygen density of 16.1×10¹⁷ atoms/cc (ASTM F-121, 1979) and specific resistance of 10 to 20 Ωcm, no nitrogen dope) having a diameter of 200 nm and performing mirror-finish processing thereon, a thermal treatment at 1150° C. for 3 seconds was performed by a thermal treatment furnace using a halogen lamp as its heat source.

Furthermore, on each of the plurality of silicon wafers subjected to the thermal treatment, a silicon epitaxial layer was grown to 4.0 μm under a condition that a stacking temperature was 1150° C. A defect-free depth and BMD density of each of the obtained silicon epitaxial wafers were measured under the same condition as that in the example 1. The defect-free depth was 5.1 μm and the BMD density was 0.87×10⁵ pieces/cm².

### EXAMPLE 14

Comparing with the example 13, other than changing the initial interstitial oxygen density of the silicon single crystal ingot to 16.6×10¹⁷ atoms/cc (ASTM F-121, 1979) and changing the nitrogen density to 34.0×10¹³ atoms/cc; a wafer was produced under the same condition as that in the example 13. Then, the defect-free depth and the BMD density were measured. The results were 5.6 μm in the defect-free depth and 3.5×10⁵ pieces/cm².

### EXAMPLE 15

Comparing with the example 13, other than changing the initial interstitial oxygen density of the silicon single crystal ingot to 15.1×10¹⁷ atoms/cc (ASTM F-121, 1979), using a flash lamp thermal treatment furnace using a xenon lamp instead of the halogen lamp thermal treatment furnace, performing a thermal treatment at 1250° C. for 0.001 second by using the flash lamp thermal treatment furnace, and changing the film thickness of the epitaxial layer to 3.5 μm; a wafer was produced under the same condition as that in the example 13. Then, the defect-free depth and the BMD density were measured. The results were 4.3 μm in the defect-free depth and 7.7×10⁵ pieces/cm².

### EXAMPLE 16

Comparing with the example 13, other than changing the initial interstitial oxygen density of the silicon single crystal ingot to 17.8×10¹⁷ atoms/cc (ASTM F-121, 1979), changing the nitrogen density to 27.0×10¹³ atoms/cc, using a flash lamp thermal treatment furnace using a xenon lamp instead of the halogen lamp thermal treatment furnace, performing a thermal treatment at 1250° C. for 0.001 second by using the flash lamp thermal treatment furnace, and changing the film thickness of the epitaxial layer to 3.5 μm; a wafer was produced under the same condition as that in the example 13. Then, the defect-free depth and the BMD density were measured. The results were 4.61 μm in the defect-free depth and 12.0×10⁵ pieces/cm².

### EXAMPLE 17

Comparing with the example 13, other than changing the initial interstitial oxygen density of the silicon single crystal ingot to 16.4×10¹⁷ atoms/cc (ASTM F-121, 1979), using a laser thermal treatment furnace using a laser instead of the halogen lamp thermal treatment furnace, performing a thermal treatment at 1350° C. for 0.001 second by using the laser thermal treatment furnace, and changing the film thickness of the epitaxial layer to 3.5 μm; a wafer was produced under the same condition as that in the example 13. Then, the defect-free depth and the BMD density were measured. The results were 4.7 μm in the defect-free depth and 8.7×10⁵ pieces/cm².

### EXAMPLE 18

Comparing with the example 13, other than changing the initial interstitial oxygen density of the silicon single crystal ingot to 17.8×10¹⁷ atoms/cc (ASTM F-121, 1979), changing the nitrogen density to 24.0×10¹³ atoms/cc, using a laser thermal treatment furnace using a laser instead of the halogen lamp thermal treatment furnace, performing a thermal treatment at 1350° C. for 0.001 second by using the laser thermal treatment furnace, and changing the film thickness of the epitaxial layer to 3.5 μm; a wafer was produced under the same condition as that in the example 13. Then, the defect-free depth and the BMD density were measured. The results were 4.3 μm in the defect-free depth and 32.0×10⁵ pieces/cm².

### COMPARATIVE EXAMPLE 5

Comparing with the example 13, other than changing the initial interstitial oxygen density of the silicon single crystal ingot to 15.8×10¹⁷ atoms/cc (ASTM F-121, 1979) and performing a thermal treatment at 1125° C. for 3 seconds by using a halogen lamp thermal treatment furnace; a wafer was produced under the same condition as that in the example 13. Then, the defect-free depth and the BMD density were measured. The results were 0.96×10⁵ pieces/cm² in the BMD density but 0 μm in the defect-free depth.

TABLE 2

| | | | Thermal Treatment with Rapid | | | Epitaxial | | |
|---|---|---|---|---|---|---|---|---|
| | Silicon Ingot | | Heating Up and Down | | | Growth | Defect- | |
| | Oxygen | Nitrogen | Thermal | | | Film | Free | BMD |
| | Density | Density | Treatment | Temperature | Duration | Thickness | Depth | Density |
| | (×10¹⁷ atoms/cc) | (×10¹³ atoms/cc) | Furnace | (° C.) | (second) | (μm) | (μm) | (×10⁵ pieces/cm²) |
| Example 13 | 16.1 | no dope | halogen | 1150 | 3 | 4.0 | 5.1 | 0.87 |
| | | | lamp | | | | | |
| Example 14 | 16.6 | 34.0 | halogen | 1150 | 3 | 4.0 | 5.6 | 3.5 |
| | | | lamp | | | | | |
| Example 15 | 15.1 | no dope | flash lamp | 1250 | 0.001 | 3.5 | 4.3 | 7.7 |
| Example 16 | 17.8 | 27.0 | flash lamp | 1250 | 0.001 | 3.5 | 4.6 | 12.0 |
| Example 17 | 16.4 | no dope | laser | 1350 | 0.001 | 3.5 | 4.7 | 8.7 |
| Example 18 | 17.3 | 24.0 | laser | 1350 | 0.001 | 3.5 | 4.3 | 32.0 |
| Comparative | 15.8 | no dope | halogen | 1125 | 3 | 4.0 | 0.0 | 0.96 |
| Example 5 | | | lamp | | | | | |

### [Considerations]

From the results of the examples 13 to 18, it was confirmed that, when performing a thermal treatment at 1350° C. or lower for not longer than 3 seconds on a wafer having an initial interstitial oxygen density of 1.4×10¹⁸ atoms/cc (ASTM F-121, 1979) and, then, forming a silicon epitaxial layer thereon, a defect-free layer of about 6 μm was formed on the obtained wafer. Also, a high BMD density was observed on an area being 10 to 20 μm from the wafer surface.

On the other hand, in the comparative example 5 wherein the thermal treatment with rapid heating up and down was at 1125° C., oxygen precipitation nuclei in the wafer surface layer were not sufficiently eliminated by the thermal treatment. It was confirmed that epitaxial defects arose from the oxygen precipitation nuclei during the epitaxial growth and the oxide film breakdown voltage was deteriorated.

### EXAMPLE 19

On a plurality of silicon wafers obtained by slicing a silicon single crystal ingot (having an initial interstitial oxygen density of 14.5×10¹⁷ atoms/cc (ASTM F-121, 1979) and specific resistance of 10 to 20 Ωcm, no nitrogen dope) having a diameter of 200 nm and performing mirror-finish processing thereon, a thermal treatment at 1150° C. for 3 seconds was performed by a thermal treatment furnace using a halogen lamp as its heat source.

On the silicon wafers subjected to the thermal treatment, an additional thermal treatment at 1000° C. was furthermore performed for 30 minutes in an argon gas atmosphere.

When measuring defect-free depths and BMD densities of the obtained silicon wafers under the same condition as that in the example 1, the defect-free depth was 2.3 μm and the BMD density was 2.3×10⁵ pieces/cm².

### EXAMPLE 20

Comparing with the example 19, other than changing the condition of the additional thermal treatment to 1200° C. for 60 minutes, a wafer was produced under the same condition as that in the example 19. Then, the defect-free depth and the BMD density were measured. The results were 5.6 μm in the defect-free depth and 1.1×10⁵ pieces/cm² in the BMD density.

Also, when observing the BMD size with a transmission electron microscope before and after the additional thermal treatment, the size was smaller (<10 nm) than the minimum size detectable with a transmission electron microscope before performing the additional thermal treatment, however, after the additional thermal treatment, a precipitate in polyhedral shapes having an average size of 63.4 nm was observed.

### EXAMPLE 21

Comparing with the example 19, other than changing the initial interstitial oxygen density of the silicon single crystal ingot to 14.6×10¹⁷ atoms/cc (ASTM F-121, 1979), using a flash lamp thermal treatment furnace using a xenon lamp instead of a halogen lamp, performing a thermal treatment with rapid heating up and down at 1250° C. for 0.001 second, and changing a condition of the additional thermal processing to 1150° C. for 30 minutes; a wafer was produced under the same condition as that in the example 19. Then, the defect-free depth and the BMD density were measured. The results were 2.1 μm in the defect-free depth and 19.0×10⁵ pieces/cm² in the BMD density.

### EXAMPLE 22

Comparing with the example 19, other than changing the initial interstitial oxygen density of the silicon single crystal ingot to 14.6×10¹⁷ atoms/cc (ASTM F-121, 1979), using a flash lamp thermal treatment furnace using a xenon lamp instead of a halogen lamp, performing a thermal treatment with rapid heating up and down at 1250° C. for 0.001 second, and changing a condition of the additional thermal processing to 1150° C. for 60 minutes; a wafer was produced under the same condition as that in the example 19. Then, the defect-free depth and the BMD density were measured. The results were 3.5 μm in the defect-free depth and 12.0×10⁵ pieces/cm² in the BMD density.

### EXAMPLE 23

Comparing with the example 19, other than changing the initial interstitial oxygen density of the silicon single crystal ingot to 14.4×10¹⁷ atoms/cc (ASTM F-121, 1979), using a laser thermal treatment furnace using a laser instead of a halogen lamp, performing a thermal treatment with rapid heating up and down at 1300° C. for 0.001 second, and changing the condition of the additional thermal processing to 1150° C. for 30 minutes; a wafer was produced under the same condition as that in the example 19. Then, the defect-free depth and the BMD density were measured. The results were 3.7 μm in the defect-free depth and 10.0×10⁵ pieces/cm² in the BMD density.

### EXAMPLE 24

Comparing with the example 19, other than changing the initial interstitial oxygen density of the silicon single crystal ingot to 14.7×10¹⁷ atoms/cc (ASTM F-121, 1979), changing the nitrogen density to 85.8×10¹³ atoms/cc, performing a thermal treatment with rapid heating up and down at 1200° C. for 5 seconds by using a halogen lamp, and changing the condition of the additional thermal processing to 1150° C. for 60 minutes; a wafer was produced under the same condition as that in the example 19. Then, the defect-free depth and the BMD density were measured. The results were 4.9 μm in the defect-free depth and 24.0×10⁵ pieces/cm² in the BMD density.

TABLE 3

| | | | Thermal Treatment with Rapid Heating | | | | | | |
|---|---|---|---|---|---|---|---|---|---|
| | Silicon Ingot | | Up and Down | | | Additional Thermal | | Defect- | |
| | Oxygen | Nitrogen | Thermal | | | Treatment | | Free | BMD |
| | Density | Density | Treatment | Temperature | Duration | Temperature | Duration | Depth | Density |
| | (×10¹⁷ atoms/cc) | (×10¹³ atoms/cc) | Furnace | (° C.) | (second) | (° C.) | (second) | (μm) | (×10⁵ pieces/cm²) |
| Example 19 | 14.5 | no depe | halogen lamp | 1150 | 3 | 1000 | 30 | 2.3 | 2.3 |
| Example 20 | 14.5 | no depe | halogen lamp | 1150 | 3 | 1200 | 60 | 5.6 | 1.1 |
| Example 21 | 14.6 | no depe | flash lamp | 1250 | 0.001 | 1150 | 30 | 2.1 | 19.0 |
| Example 22 | 14.6 | no depe | flash lamp | 1250 | 0.001 | 1150 | 60 | 3.5 | 12.0 |
| Example 23 | 14.4 | no depe | laser | 1300 | 0.001 | 1150 | 30 | 3.7 | 10.0 |
| Example 24 | 14.7 | 85.8 | halogen lamp | 1200 | 5 | 1150 | 60 | 4.9 | 24.0 |

### [Considerations]

From the results of the examples 19 to 24, it was confirmed that sizes of an oxygen precipitate increase at an area being 10 to 20 μm from the wafer surface by performing an additional thermal treatment (nonoxidizing atmosphere) on a wafer subjected to a thermal treatment with rapid heating up and down (example 20). As a result, thermal stability improves at the area being 10 to 20 μm and, moreover, a defect-free depth becomes adjustable because the BMD in the surface layer was eliminated due to an outward diffusion of oxygen near the surface layer.

### Second Embodiment

First, the configuration of a single crystal pulling apparatus capable of producing a silicon ingot (hereinafter, also referred to as a single crystal) having a constant diameter part with no Grown-in defect will be explained briefly.

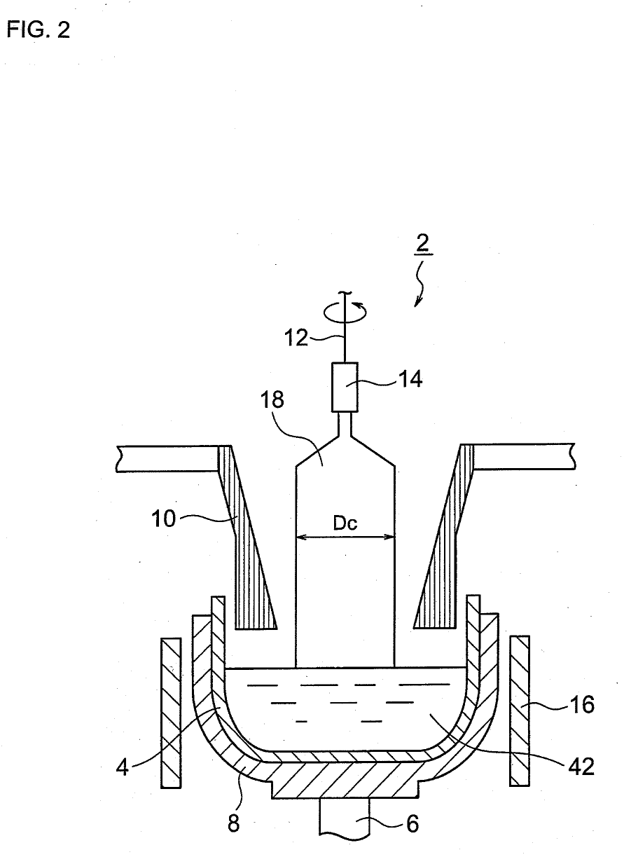

In the present embodiment, a single crystal pulling apparatus 2, for example, shown in FIG. 2 is used. In the pulling apparatus shown in FIG. 2, there is a crucible 4 inside a device body which is kept to be airtight. The crucible 4 is arranged inside a crucible holding container 8 supported by a-crucible support axis 6. A heat shield 10 for forming a hot zone structure is arranged above the crucible 4. The heat shield 10 in the present embodiment is configured that the outer shell is formed by black lead and the inside is filled with black lead felt.

In an opening of the heat shield 10, a pull-up axis 12 is inserted to be able to be freely pulled up to above while rotating. A seed chuck 14 is attached to the lower end of the pull-up axis 12. On the seed chuck 14, a seed crystal (not shown) is attached, and a power source (not shown) is connected to the upper end of the pull-up axis 12.

A heater 16 is arranged on an outer circumference of the crucible holding container 8. By activating the heater 16, the crucible 4 is heated and melt 42 in the crucible 4 is kept at a predetermined temperature.

In the single crystal pulling apparatus 2 of the present embodiment, an improvement is made on the hot zone structure, such as a material, size and position of the heat shield 10 surrounding a silicon single crystal 18 being immediately after solidification; so that an crystal internal temperature gradient in the pull-up axis 12 direction becomes gentle on the crystal circumferential portion (Ge) side comparing with that on the crystal center portion (Gc) side in a temperature range from a melting point of silicon (1419° C.) to close to 1250° C. As a result, during the pulling-up, a temperature of the surface portion is kept by heat radiation from a wall surface of the crucible 4 and a surface of the melt 42 in the vicinity of a portion right after coming out from the melt 42 of the single crystal, and the upper portion of the single crystal is strongly cooled by using the heat shield 10 and a cooling member, etc.; therefore, the crystal center portion (Gc) is cooled due to a heat transfer and the temperature gradient can become relatively steep on the center portion side.

By using the pulling apparatus 2 configured as explained above, a silicon ingot is produced by a normal method, for example, by the CZ method.

(1) First, polycrystal of a high-purity silicon is put in the crucible 4 of the single crystal pulling apparatus 2, then, the crucible 4 is rotated by the crucible support axis 6 in a reduced-pressure atmosphere, the heater 16 is activated to melt the polycrystal of the high-purity silicon and melt 42 is obtained.

(2) Next, by moving the crystal pull-up axis 12 downwardly, a seed crystal (not shown) attached to the seed chuck 14 at the lower end of the axis 12 is brought to contact with the melt 42 in the crucible 4.

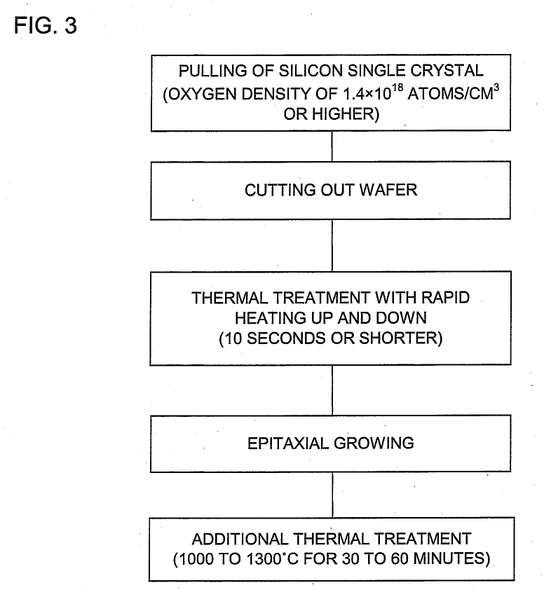

(3) Next, by pulling up the seed crystal while rotating the pull-up axis 12, the melt 42 adhered to the seed crystal is solidified and a crystal is grown so as to grow a silicon ingot 18 (pulling up of silicon single crystal: refer to FIG. 3). In the present embodiment, when pulling up, the seed is narrowed so as not to cause any crystal dislocation, then, the crown portion is formed and the going to shoulder to form a constant diameter part.

### [Growing Silicon Ingot]

In the present embodiment, first, growing of a silicon ingot 18 is performed under a condition by which a value of the interstitial oxygen density [Oi] becomes large (high oxygen density), specifically, 1.4×10¹⁸ atoms/cm³ or larger. When oxygen density of the grown silicon ingot 18 is lower than 1.4×10¹⁸ atoms/cm³, stable oxygen precipitate to be a gettering source does not exist by a valid number immediately beneath the thin film device active layer.

Secondly, growing of a silicon ingot 18 is performed under a condition by which the constant diameter part becomes a defect-free area with no Grown-in defect. For example, a seed crystal is pulled up in a state where an atmosphere gas obtained by mixing a hydrogen atom-containing material in an inert gas is introduced into the apparatus 2.

As the inert gas, an inexpensive Ar gas is preferable, but other than that, a variety of noble gas simple substances, such as He, Ne, Kr and Xe, and mixed gas of these may be used.

The hydrogen atom-containing material indicates a material which is thermally decomposed when dissolved in the melt 42 and capable of supplying hydrogen atoms into the melt 42. As a result that the hydrogen atom-containing material is included in an inert gas to be introduced as an atmosphere gas to the apparatus 2, hydrogen density in the melt 42 can be improved. As the hydrogen atom-containing material, inorganic compounds containing hydrogen atoms, such as a hydrogen gas, H₂O and HCl; carbon hydrides, such as silane gas, CH₄, C₂ and H₂; and a variety of materials containing hydrogen atoms, such as alcohol and carboxylic acid; may be mentioned. Among them, it is preferable to use a hydrogen gas.

In the present embodiment, an atmosphere inside the apparatus 2 is controlled to be an inert gas atmosphere having a hydrogen partial pressure of 40 Pa or higher and 160 Pa or lower. By controlling the hydrogen partial pressure inside the apparatus 2 to be within this range and selecting a pulling speed to be in a range of 0.4 to 0.6 mm/minute and preferably 0.43 to 0.56 mm/minute, it is possible to easily grow a silicon ingot from which wafers having a PV area (an area where oxide precipitate is accelerated or a defect-free area where vacancies are enriched) on allover the surface can be cut out. By setting the hydrogen partial pressure to be 40 Pa or higher, it is possible to prevent a pulling speed range for obtaining a defect-free area where vacancies are enriched from becoming narrow. On the other hand, by setting the hydrogen partial pressure to be 160 Pa or lower, it is possible to effectively prevent PI areas (an area where oxygen precipitate is suppressed or a defect-free area where interstitial silicon atoms are enriched) from being mixed on the cut out wafers. In the wafer of PV areas, BMD is easily formed and, for example, when performing so-called DZ (Denuded Zone) layer forming processing on the surface, BMD having gettering action is easily formed therein. On the PI areas, BMD is hardly formed.

A pressure of an atmosphere gas inside the apparatus 2 is not particularly limited as far as a hydrogen partial pressure is within the predetermined range as explained above and a normally adoptable condition will be sufficient.

In the present embodiment, when an oxygen gas (O₂) exists in an inert atmosphere, it is preferable to control an atmosphere, so that a density difference becomes 3 volume % or larger between a density of the gas calculated in terms of hydrogen molecules and twice the oxygen gas density. By controlling the density difference between the density of the hydrogen atom-containing gas calculated in terms of hydrogen molecules and twice the oxygen gas density to 3 volume % or larger, an ingot obtains an effect that arising of Grown-in defects, such as COP and dislocation cluster, is suppressed due to hydrogen atoms taken in the silicon ingot.

In the present embodiment, when a normal furnace internal pressure is in a range of 1.3 to 13.3 kPa (10 to 100 Torr), a nitrogen density in an inert atmosphere is preferably controlled to 20 volume % or lower. By controlling the nitrogen density in the inert atmosphere to 20 volume % or lower, occurrence of dislocation of a silicon single crystal can be prevented.

When adding a hydrogen gas as a gas of a hydrogen atom-containing material, it may be supplied from a hydrogen gas cylinder, a hydrogen gas storage tank and a tank filled with a hydrogen storing alloy, etc. to an inert atmosphere in the apparatus 2 through an exclusive pipe.

As to the introduction of an inert gas containing a hydrogen atom-containing material into an atmosphere in the apparatus 2 in the present embodiment, it is sufficient if a hydrogen atom-containing material is included in an inert gas and the result is introduced to the apparatus 2 at least while pulling up the constant diameter part as a required diameter of the single crystal. It is because hydrogen has a characteristic of being easily dissolved in melt 42 in a short time, it is sufficient to be included in the atmosphere only while pulling up the constant diameter part to obtain the effect sufficiently. Also, in terms of safety ensuring of handling hydrogen, it is preferable not to use it beyond necessity. Accordingly, at the stages of melting polycrystal in the crucible 4, removing a gas, immersing a seed crystal, necking and forming of a crown portion, it is not necessary to make the hydrogen atom-containing material included in the inert gas to be introduced to the apparatus 2. It is also the same at the stage of finishing growing, forming a cone by reducing the diameter and removing from the melt 42.

The silicon ingot 18 grown through the above procedure has no Grown-in defect and, moreover, the interstitial oxygen density [Oi] is as high as 1.4×10¹⁸ atoms/cm³ or higher. The [Oi] value here means a measurement value based on the Fourier transform infrared spectrophotometric method standardized by ASTM F-121 (1979).

In the present embodiment, an atmosphere in the apparatus 2 is set to be a specific atmosphere to pull up a single crystal. Therefore, even if an oxygen density in the obtained ingot becomes high, oxygen precipitate can be suppressed in device active regions in the cut out wafers and circuit characteristics are not deteriorated. However, when the oxygen density becomes too high, the precipitate suppressing effect is lost, so that the oxygen density is preferably controlled to be not higher than 1.6×10¹⁸ atoms/cm³.

(4) Next, wafers are cut out from the grown silicon ingot 18 (wafer processing: refer to FIG. 3). The cuffing processing for obtaining wafers is not particularly limited and general cut-out processing methods may be used. Here, wafers are cut out from a silicon ingot 18 with no Grown-in defect existing therein and no Grown-in defect is generated.

Alternately, before cutting out wafers from the grown silicon ingot 18, nitrogen may be doped in a density range of 1×10¹² to 5×10¹⁴ atoms/cm³ and/or carbon may be doped in a density range of 5×10¹⁵ to 2×10¹⁷ atoms/cm³ into the ingot crystal. When pulling up the single crystal, an inert gas containing a hydrogen atom-containing material may be used as the atmosphere gas. In this way, also, a defect-free area where BMD are plentifully generated, that is, a PV area can be increased.

Here, values of the dope densities of nitrogen and carbon are measurement values based on ASTM F-123 (1981).

(5) Next, a thermal treatment with rapid heating up and down at 1000° C. or higher for not longer than 10 seconds is performed on the cut out wafers (thermal treatment with rapid heating up and down: refer to FIG. 3).

By performing a thermal treatment with rapid heating up and down at 1000° C. or higher for not longer than 10 seconds on a wafer, it is possible to obtain a wafer wherein a defect-free layer is formed on the wafer surface and an oxygen precipitate to be a gettering source exists immediately beneath the device active layers (10 to 20 μm from the wafer surface).

In the present embodiment, the thermal treatment with rapid heating up and down is preferably performed at a temperature of 1000° C. or higher but not higher than the melting point of silicon (1410° C.). When performing at 1000° C. or higher, a defect-free layer can be formed on the wafer surface.

In the present embodiment, the thermal treatment with rapid heating up and down is preferably performed in a nonoxidizing atmosphere, for example, in an atmosphere of an argon gas, nitrogen gas, hydrogen gas or a mixed gas of these.

In the present embodiment, the thermal treatment with rapid heating up and down may be performed by using a halogen lamp thermal treatment furnace using a halogen lamp as a heat source, a flash lamp thermal treatment furnace using a xenon lamp as a heat source or a laser thermal treatment furnace using-a laser as a heat source. Duration of the thermal treatment is preferably 0.1 to 10 seconds when using a halogen lamp thermal treatment furnace, 0.1 second or shorter when using a flash lamp thermal treatment furnace and 0.1 second or shorter when using a laser thermal treatment furnace.

(6) Note that, in the present embodiment, a silicon epitaxial layer may be grown on the wafer surface after the thermal treatment with rapid heating up and down (epitaxial growing: refer to FIG. 3). Since a defect-free layer is formed on the wafer surface subjected to the thermal treatment with rapid heating up and down, by forming an epitaxial layer thereon, the defect-free layer can be furthermore increased or a thickness of the defect-free layer can be adjusted.

In the present embodiment, a wafer after the thermal treatment with rapid heating up and down may be furthermore subjected to an additional thermal treatment in a nonoxidizing atmosphere, for example, in an atmosphere of an argon gas, nitrogen gas, hydrogen gas or a mixed gas of these (additional thermal treatment: refer to FIG. 3). By performing an additional thermal treatment on the wafer after performing the thermal treatment with rapid heating up and down, a size of an oxygen precipitate existing immediately beneath the device active layer can become larger and a thickness of the defect-free layer can be also adjusted.

A temperature of the additional thermal treatment in this case is about 1000 to 1300° C. and the duration is 30 to 60 minutes or so.

(7) Through the above procedure, a silicon wafer of the present embodiment is produced. The thus obtained silicon wafer does not have any Grown-in defects in the device active region near the wafer surface, namely, it is defect-free. Also, the silicon wafer obtained in the present embodiment is cut out from a silicon ingot 18 wherein an interstitial oxygen density [Oi] is 1.4×10¹⁸ atoms/cm³ or higher, therefore, there are BMD by the number of 5×10⁴ pieces/cm² immediately beneath the device active region. Namely, the silicon wafer produced by the above procedure of the present embodiment becomes a defect-free wafer requiring BMD.

### EXAMPLE 1

Next, the present invention will be explained further in detail by taking examples embodying the second embodiment explained above. Note that the present invention is not limited to the examples.

A single crystal pulling apparatus 2 shown in FIG. 2 was prepared. As the heat shield 10, one configured that the outer shell was formed by a black lead and the inside was filled with black lead was used.

By using such a single crystal pulling apparatus 2, first, polycrystal of high-purity silicon was put in a crucible 4 of the single crystal pulling apparatus 2. Then, the crucible 4 was rotated by a crucible support axis 6 in a reducing atmosphere and, at the same time, a heater 16 was activated to melt the high-purity silicon polycrystal and obtain melt 42.

Next, by moving the crystal pulling axis 12 downwardly, a seed crystal (not shown) attached to a seed chuck 14 at a lower end of the axis 12 was brought to contact with the melt 42 in the crucible 4.

Next, the seed crystal was pulled upwardly while rotating the pulling axis 12, the seed was narrowed for not causing any crystal dislocation, a crown portion was formed, then, going to shoulder to form a constant diameter part (silicon ingot 18).

In the present example, a targeted diameter of the constant diameter part (Dc: refer to FIG. 2) was 200 mm, and an axis direction temperature gradient inside the growing single crystal was in a range from the melting point to 1370° C.; wherein the crystal center portion (Gc) was 3.0 to 3.2° C./mm and the crystal circumferential portion (Ge) was 2.3 to 2.5° C./mm. Also, a pressure of an atmosphere in the apparatus 2 was set to 4000 Pa and a pulling speed was 0.52 mm/minute to grow a single crystal. In that case, a hydrogen partial pressure in the atmosphere in the apparatus 2 was controlled to 250 Pa to grow a silicon single crystal.

As a result, a silicon ingot (specific resistance was 10 to 20 Ωcm and no nitrogen dope) having a constant diameter part (about 200 mm) with no Grown-in defect was obtained with values of interstitial oxygen density shown in Table 1. Note that the values of [Oi] here means measurement values based on the Fourier transform infrared spectrophotometric method standardized by ASTM F-121 (1979).

Next, wafers were cut out from the obtained silicon ingot and mirror-finish processing was performed thereon.

Next, on the obtained plurality of silicon wafers, a thermal treatment with rapid heating up and down was performed by using heat sources shown in Table 1, in an argon gas atmosphere and by temperatures and durations shown in Table 1 to obtain wafer samples (samples 1 to 11). Also, other sample wafers 1 to 3 and 11 were prepared and a silicon epitaxial layer was grown thereon under a stacking temperature condition of 1150° C., so that silicon epitaxial wafer samples (samples 12 to 15) were obtained.

On the obtained wafer samples (samples 1 to 15), a defect-free depth and oxygen precipitate (BMD) density were evaluated.

The “defect-free depth” was obtained as explained below. First, on the wafers samples subjected to the thermal treatment with rapid heating up and down (samples 1 to 11) or the wafer samples after being grown epitaxial thereon (samples 12 to 15), a thermal treatment at 800° C. for four hours and 1000° C. for 16 hours was performed. Then, each of the wafers after the thermal treatment was re-polished by about 0.2 μm, so as to prepare wafers with different re-polished amounts from their surfaces. Next, on the wafers each having a different re-polished amount from its surface, an oxide film having a thickness of 25 nm and a MOS capacitor having a measurement electrode (phosphorus-doped polysilicon electrode) having an area of 8 mm² were formed. Then, oxide film breakdown voltage characteristics (TZDB method) were measured under a condition that an electric field for judging was 11 Mv/cm (it was considered breakdown when a current value exceeds 10⁻³ A) and MOS capacitors which cleared the judging electric field were considered to be good. A maximum re-polished amount, with which a good rate became 90%, was obtained and regarded as the defect-free depth (μm).

The “BMD density” was obtained as explained below. First, on the wafers samples subjected to the thermal treatment with rapid heating up and down (samples 1 to 11) or the wafer samples after being grown epitaxial thereon (samples 12 to 15), a thermal treatment at 800° C. for four hours and 1000° C. for 16 hours was performed. Then, the wafers were cleaved and wright etching of 2 μm was performed thereon. Then etching pits existing at an area being 3 to 10 μm from the wafer surface were measured with an optical microscope and BMD density (×10⁵ pieces/cm²) was calculated.

The results of the defect-free depth and BMD density are shown in Table 4 with interstitial oxygen density [Oi] and a condition of the thermal treatment with rapid heating up and down.

TABLE 4

| | Silicon Ingot | | Wafer | | | | | |
|---|---|---|---|---|---|---|---|---|
| | Interstitial | | Thermal Treatment with Rapid | | | Epitaxial | | |
| | Oxygen | | Heating Up and Down | | | Growth | Evaluation | |
| | Density | | Thermal | | | Film | Defect- | BMD |
| | [Oi] | Grown-in | Treatment | Temperature | Duration | Thickness | Free Depth | Density |
| Sample No. | (×10¹⁷ atoms/cm3) | Defect | Furnace | (° C.) | (second) | (μm) | (μm) | (×10⁵ pieces/cm²) |
| 1 | 14.4 | none | halogen | 1000 | 5 | — | 2 | 3.1 |
| | | | lamp | | | | | |
| 2 | 14.3 | none | flash lamp | 1200 | 0.001 | — | 1.2 | 4 |
| 3 | 14.2 | none | laser spike | 1300 | 0.001 | — | 1.4 | 5.1 |
| 4 | 20.1 | none | halogen | 1000 | 3 | — | 1.6 | 4.7 |
| | | | lamp | | | | | |
| 5 | 19.7 | none | flash lamp | 1200 | 0.001 | — | 0.8 | 5.1 |
| 6 | 20.8 | none | laser spike | 1300 | 0.001 | — | 1 | 4.3 |
| 7 | 11.2 | none | halogen | 1000 | 5 | — | >5 | <0.01 |
| (Comparative | | | lamp | | | | | |
| Example) | | | | | | | | |
| 8 | 12.3 | none | flash lamp | 1200 | 0.001 | — | >5 | <0.01 |
| (Comparative | | | | | | | | |
| Example) | | | | | | | | |
| 9 | 14.8 | none | — | | | — | 0 | 4.57 |
| (Comparative | | | | | | | | |
| Example) | | | | | | | | |
| 10 | 14.1 | none | halogen | 1000 | 11 | — | >5 | 0.3 |
| (Comparative | | | lamp | | | | | |
| Example) | | | | | | | | |
| 11 | 15.1 | none | halogen | 950 | 5 | — | 0.4 | 6.2 |
| | | | lamp | | | | | |
| 12 | 14.4 | none | halogen | 1000 | 5 | 3 | 5.4 | 1.8 |
| | | | lamp | | | | | |
| 13 | 14.3 | none | flash lamp | 1200 | 0.001 | 3 | 4.8 | 0.89 |
| 14 | 13.2 | none | laser spike | 1300 | 0.001 | 3 | 4.6 | 1.1 |
| 15 | 15.1 | none | halogen | 950 | 5 | 3 | 3.4 | 3.1 |
| | | | lamp | | | | | |

From Table 4, the followings can be found out.

(1) In the wafer samples (samples 1 to 6) cut out from a silicon ingot having a constant diameter part with no Grown-in defect wherein an interstitial oxygen density [Oi] was 1.4×10¹⁸ atoms/cm³, firstly, the fact was found that a defect-free depth of 2 μm or shallower was formed. This is presumed to indicate that, although only in extremely surface areas, oxygen precipitation nuclei formed at the time of CZ pulling were eliminated due to the thermal treatment with rapid heating up and down and high oxide film breakdown voltage was exhibited in that areas. Note that the wafer samples 1 to 6 are defect-free wafers without any COP or dislocation cluster existing therein, therefore, defects that exist after the crystal growing were oxygen precipitation nuclei only.

Secondly, at areas deeper than 3 μm from the wafer surface, the fact that the BMD density was high was found. It is presumed that oxygen stable precipitation nuclei which were grown due to high oxygen at the time of the crystal growth were not eliminated by the thermal treatment with rapid heating up and down and the existence became apparent by a thermal treatment at 800° C. for four hours and 1000° C. for 16 hours.

As explained above, according to the samples 1 to 6, it was confirmed that it is possible to produce a wafer wherein the area being 2 μm or shallower corresponding to a device active region was defect-free and oxygen precipitate (gettering source) valid for impurity gettering exists at a high density immediately beneath the device active layer.

(2) On the other hand, it was found that wafer samples (samples 7 and 8) cut out from a silicon ingot having a constant diameter part with no Grown-in defect but having a low oxygen density, such that the interstitial oxygen density [Oi] was lower than 1.4×10¹⁸ atoms/cm³; a defect-free depth (defect-free layer) of 5 μm or deeper was formed. However, it was found that heat stability was poor in the oxygen precipitate formed at the time of growing crystal and the BMD density was low at an area being deeper than 3 μm from the wafer surface.

(3) Even in a wafer sample cut out from a silicon ingot having a constant diameter part with no Grown-in defect and having an interstitial oxygen density [Oi] of 1.4×10¹⁸ atoms/cm³ or higher, when the thermal treatment with rapid heating up and down was not performed thereon (sample 9); it was found that due to an effect of an existence of oxygen precipitation nuclei formed at the time of crystal growing, a defect-free width was not able to be obtained.

(4) Even in a wafer sample cut out from a silicon ingot having a constant diameter part with no Grown-in defect, having an interstitial oxygen density [Oi] of 1.4×10¹⁸ atoms/cm³ or higher and also subjected to the thermal treatment with rapid heating up and down, when treatment duration of the thermal treatment with rapid heating up and down was long (sample 10); a defect-free depth (defect-free layer) of 5 μm or deeper was formed, and the BMD density was liable to be low at a deeper area than 3 μm from the wafer surface. It was found that, in a wafer sample with a relatively low treatment temperature (sample 11), there was a tendency that a defect-free width was hard to be obtained. Note that when the treatment temperature here exceeds the melting point of silicon (1410° C.), the wafer melts.

(5) In the wafer samples (samples 12 to 15) cut out from a silicon ingot having a constant diameter part with no Grown-in defect and having an interstitial oxygen density [Oi] of 1.4×10¹⁸ atoms/cm³ or higher; even if an epitaxial layer was grown after the thermal treatment with rapid heating up and down, it was found that a defect-free depth (defect-free layer) of about 61 μm or shallower was formed on the obtained wafer and, moreover, the BMD density was high at a deep area of 7 to 15 μm from the wafer surface. Namely, it was confirmed that, by combining epitaxial growing in this way, a wafer having any defect-free layer width can be produced.

Note that in the wafer sample (sample 15) wherein a treatment temperature in the thermal treatment with rapid heating up and down was relatively low; it was confirmed that a defect-free depth (defect-free layer) was formed closer to the wafer surface comparing with those in the sample wafers 12 to 14, and BMD of a sufficient density existed immediately beneath the device active region.

What is claimed is:

1. A production method of a silicon single crystal wafer, obtained by processing a single crystal grown by the Czochralski method; comprising a step of performing a thermal treatment with rapid heating up and down for 10 seconds or shorter on a wafer having an initial interstitial oxygen density of 1.4×10¹⁸ atoms/cc (ASTM F-121,1979) or higher.

2. The production method of a silicon single crystal wafer as set forth in claim 1, wherein the thermal treatment with rapid heating up and down is performed in an atmosphere of an argon gas, nitrogen gas, hydrogen gas or a mixed gas of these with a thermal treatment temperature of 1150° C. or higher but not higher than a silicon melting point.

3. The production method of a silicon single crystal wafer as set forth in claim 1, wherein the thermal treatment with rapid heating up and down is performed by using a halogen lamp as a heat source with a thermal treatment of 0.1 to 10 seconds.

4. The production method of a silicon single crystal wafer as set forth in claim 1, wherein the thermal treatment with rapid heating up and down is performed by using a xenon lamp as a heat source with a thermal treatment of 0.1 second or shorter.

5. The production method of a silicon single crystal wafer as set forth in claim 1, wherein the thermal treatment with rapid heating up and down is performed by using a laser as a heat source with a thermal treatment of 0.1 second or shorter.

6. The production method of a silicon single crystal wafer as set forth in claim 1, wherein nitrogen is doped in a silicon single crystal by 1×1013 to 1×1015 atoms/cc when growing the silicon single crystal by the Czochralski method.

7. The production method of a silicon single crystal wafer as set forth in claim 1, comprising a step of epitaxially growing a silicon single crystal on a wafer subjected to the thermal treatment.

8. The production method of a silicon single crystal wafer as set forth in claim 1, comprising a step of performing a thermal treatment at 1000° C. or higher and 1300° C. or lower in a nonoxidizing atmosphere on the silicon single crystal wafer.

9. A production method of a silicon single crystal wafer, obtained by processing a single crystal grown by the Czochralski method; comprising a step of performing a thermal treatment so that an oxygen precipitate of 5×10⁴ pieces/cm² is formed in a range of 10 μm to 20 μm from a wafer surface when a thermal treatment at 1000° C. is performed for 16 hours on the wafer having an initial interstitial oxygen density of 1.4×10¹⁸ atoms/cc (ASTM F-121,1979) or higher.

10. A silicon single crystal wafer produced by the method as set forth in claim 1.

11. The silicon single crystal wafer as set forth in claim 10, having an oxygen precipitate of 5×10⁴ pieces/cm² or more in a range of 10 μm to 20 μm from the wafer surface.

12. A production method of a silicon single crystal wafer, obtained by performing a thermal treatment with rapid heating up and down at 1000° C. or higher for 10 seconds or shorter on a wafer cut out from a silicon ingot having a constant diameter part with no Grown-in defect, wherein an interstitial oxygen density [Oi] is 1.4×10¹⁸ atoms/cm³ or higher.

13. The production method of a silicon single crystal wafer as set forth in claim 1, wherein the thermal treatment with rapid heating up and down is performed in an atmosphere of an argon gas, nitrogen gas, hydrogen gas or a mixed gas of these with a temperature of 1000° C. or higher but not higher than a silicon melting point.

14. The production method of a silicon single crystal wafer as set forth in claim 1, wherein the thermal treatment with rapid heating up and down is performed by using a halogen lamp as a heat source for 0.1 to 10 seconds.

15. The production method of a silicon single crystal wafer as set forth in claim 1, wherein the thermal treatment with rapid heating up and down is performed by a flash lamp anneal furnace using a xenon lamp as a heat source for 0.1 second or shorter.

16. The production method of a silicon single crystal wafer as set forth in claim 1, wherein the thermal treatment with rapid heating up and down is performed by a laser spike anneal furnace using a laser as a heat source for 0.1 second or shorter.

17. The production method of a silicon single crystal wafer as set forth in claim 1, wherein epitaxial growth is performed after the thermal treatment with rapid heating up and down.

18. A silicon wafer produced by the method as set forth in claim 1, having no defect in a device active region near the wafer surface and having an oxygen precipitate of 5×10⁴ pieces/cm² or more immediately beneath the device active region.
